(19) United States
(12) Patent Application Publication
(10) Pub. No.: US 2023/0151159 A1
(43) Pub. Date: May 18, 2023

(54) COMPOUND FOR FORMING HARDMASK, HARDMASK COMPOSITION INCLUDING THE COMPOUND, AND METHOD OF MANUFACTURING INTEGRATED CIRCUIT DEVICE USING THE HARDMASK COMPOSITION

(71) Applicant: SAMSUNG ELECTRONICS CO., LTD., Suwon-si (KR)

(72) Inventors: Inoue NAOKI, Seongnam-si (KR); Hyunwoo KIM, Seongnam-si (KR); Tsunehiro NISHI, Suwon-si (KR)

(21) Appl. No.: 17/742,667

(22) Filed: May 12, 2022

(30) Foreign Application Priority Data
Nov. 18, 2021 (KR) 10-2021-0159810

(51) Int. Cl. C08G 79/08; H01L 21/311; H01L 21/033; H01L 21/027; H01L 27/108; H01L 49/02

(52) U.S. Cl. CPC C08G 79/08; H01L 21/0271; H01L 21/0332; H01L 21/0337; H01L 21/31144; H01L 27/10855; H01L 28/92

(57) ABSTRACT

A hardmask-forming compound, a hardmask composition, and a method of manufacturing an integrated circuit (IC), the hardmask-forming compound including a moiety represented by Formula 1:

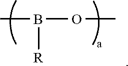

### CROSS-REFERENCE TO RELATED APPLICATION

This application is based on and claims priority under 35 U.S.C. §119 to Korean Patent Application No. 10-2021-0159810, filed on Nov. 18, 2021, in the Korean Intellectual Property Office, the disclosure of which is incorporated by reference herein in its entirety.

### BACKGROUND

### 1. Field

Embodiments relate to a hardmask-forming compound, a hardmask composition including the same, and a method of manufacturing an integrated circuit (IC) device using the hardmask composition.

### 2. Description of the Related Art

Due to the development of the electronic technology, the downscaling of IC devices has rapidly progressed. Thus, structures of the IC devices have become complicated, and aspect ratios of the structures included in the IC devices have greatly increased. Accordingly, processes of forming three-dimensional (3D) structures having high aspect ratios also have become stricter. In particular, a hardmask layer formed using a spin coating process has been used in an etching process for forming patterns having a relatively high aspect ratio during a process of manufacturing an IC device with a high integration.

### SUMMARY

The embodiments may be realized by providing a hardmask-forming compound including a moiety represented by Formula 1:

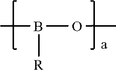

wherein, in Formula 1, R is a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, or a combination thereof, each R is separate or forms a ring along with a boron atom included in Formula 1, and a is an integer ranging from 1 to 50.

The embodiments may be realized by providing a hardmask-forming compound including a moiety represented by Formula 2:

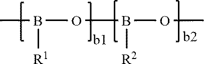

wherein, in Formula 2, R¹ and R² have different structures from each other, R¹ and R² are each independently a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof, R¹ and R² are each separately present, or at least one of R¹ and R² forms a ring along with a boron atom included in Formula 2, b1 and b2 are each independently an integer ranging from 1 to 50, and b1/(b1+b2) is in a range of 0.1 to 0.9.

The embodiments may be realized by providing a hardmask composition including the hardmask-forming compound according to an embodiment; and a solvent.

The embodiments may be realized by providing a method of manufacturing an integrated circuit, the method including forming a target structure on a substrate; forming a boron-containing hardmask structure on the target structure; forming a boron-containing hardmask structure pattern having an opening by etching the boron-containing hardmask structure; and forming a vertical hole by etching the target structure using the boron-containing hardmask structure pattern as an etch mask, the vertical hole passing through at least a portion of the target structure, wherein forming the boron-containing hardmask structure includes forming a hardmask coating layer on the target structure using a hardmask composition including a polymerized product of a boric acid that includes an organic protecting group bonded to a boron atom; and forming a boron-containing hardmask layer by annealing the hardmask coating layer, the boron-containing hardmask layer including a network system in a cross-linked network structure obtained by cross-linking the polymerized product of the boric acid.

### BRIEF DESCRIPTION OF THE DRAWINGS

Features will be apparent to those of skill in the art by describing in detail exemplary embodiments with reference to the attached drawings in which:

FIG. 1 is a flowchart of a method of manufacturing an integrated circuit (IC) device, according to embodiments;

FIGS. 2A to 2H are cross-sectional views of stages in a method of manufacturing an IC device, according to embodiments; and

FIGS. 3A to 3J are cross-sectional views of stages in a method of manufacturing an IC device, according to embodiments.

### DETAILED DESCRIPTION

A compound for forming a hardmask (hereinafter, inclusively referred to as a hardmask-forming compound) according to embodiments may include a polymerized product of boric acid including an organic protecting group bonded to a boron atom.

The hardmask-forming compound according to the embodiments may be represented by Formula 1 (e.g., may include a moiety or repeating unit represented by Formula 1).

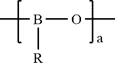

In Formula 1, R may be or may include, e.g., a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, or a combination thereof. In an implementation, each R may be separately present (e.g., pendent), or may form a ring along with a boron atom of Formula 1. a may be, e.g., an integer of 1 to 50. As used herein, the term “or” is not an exclusive term, e.g., “A or B” would include A, B, or A and B.

In an implementation, the hardmask-forming compound according to Formula 1 may have the form of a polymer. In this case, in Formula 1, a may be in a range of 5 to 50. As used herein, the term “polymer” may refer to including an oligomer and a polymer.

As used herein, a C1 to C30 alkyl group may refer to a linear or branched alkyl group having 1 to 30 carbon atoms. For example, the alkyl group may include a methyl group, an ethyl group, an n-propyl group, an isopropyl group, an n-butyl group, an isobutyl group, a secbutyl group, a tert-butyl group, a pentyl group, an isopentyl group, a neopentyl group, a tertpentyl group, a hexyl group, a 2-methylpentyl group, a heptyl group, a 1-ethylpentyl group, an octyl group, a 2-ethylhexyl group, an isooctyl group, a nonyl group, an isononyl group, a decyl group, or an isodecyl group, without being limited thereto.

As used herein, a C2 to C30 alkenyl group may include an ethenyl group, a butenyl group, or an isobutenyl group, without being limited thereto.

As used herein, a C2 to C30 alkynyl group may include an ethynyl group or a butynyl group, without being limited thereto.

As used herein, a term “aryl group” may refer to a group having at least one hydrocarbon aromatic moiety. The aryl group may refer to including a form in which hydrocarbon aromatic moieties are connected by a single bond and a non-aromatic fused ring form in which the hydrocarbon aromatic moieties are directly or indirectly fused. The aryl group may include a monocyclic functional group, a polycyclic functional group, or a fused polycyclic functional group.

As used herein, a term “heterocyclic group” may refer to including a heteroaryl group. In addition, the heterocyclic group may include at least one heteroatom selected from a nitrogen atom (N), an oxygen atom (O), a sulfur atom (S), a phosphorus atom (P), and a silicon atom (Si) instead of a carbon atom (C) in a cyclic compound including an aryl group, a cycloalkyl group, a fused ring thereof, or a combination thereof. When the heterocyclic group is the fused ring, the entire heterocyclic group or each ring thereof may include at least one heteroatom.

The aryl group may include a phenyl group, a naphthyl group, an anthracenyl group, a phenanthryl group, a naphthacenyl group, a pyrenyl group, a biphenyl group, a terphenyl group, a quaterphenyl group, a chrysenyl group, a triphenylenyl group, a perylenyl group, an indenyl group, a combination thereof, or a fused form of a combination thereof, without being limited thereto.

The heterocyclic group may include a furanyl group, a thiophenyl group, a pyrrolyl group, a pyrazolyl group, an imidazolyl group, a triazolyl group, an oxazolyl group, a thiazolyl group, an oxadiazolyl group, a thiadiazolyl group, a pyridinyl group, a pyrimidinyl group, a pyrazinyl group, a triazinyl group, a benzofuranyl group, a benzothiophenyl group, a benzimidazolyl group, an indolyl group, a quinolinyl group, an isoquinolinyl group, a quinazolinyl group, a quinoxalinyl group, a naphthyridinyl group, a benzoxazinyl group, a benzthiazinyl group, an acridinyl group, a phenazinyl group, a phenothiazinyl group, a phenoxazinyl group, a fluorenyl group, a dibenzofuranyl group, a dibenzothiphenyl group, a carbazolyl group, a pyridoindolyl group, a benzopyridooxazinyl group, a benzopyridothiazinyl group, a 9,9-dimethyl 9,10-dihydroacridinyl group, a combination thereof, or a fused form of a combination thereof, without being limited thereto. In example embodiments, the heterocyclic group or the heteroaryl group may be a pyrrole group, an indolyl group, or a carbazolyl group.

In an implementation, in Formula 1, R may have a structure substituted with a first substituent. The first substituent may include, e.g., a halogen atom, a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group, salts of the carboxyl group, a sulfonic acid group, salts of the sulfonic acid group, a phosphoric acid, phosphates, a C1 to C20 alkyl group, a C2 to C20 alkenyl group, a C2 to C20 alkynyl group, a C1 to C20 alkoxy group, a C1 to C20 halogenated alkyl group, a C6 to C30 aryl group, a C7 to C30 arylalkyl group, a C1 to C10 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C20 heterocycloalkyl group, a C6 to C30 aryl group in which some of carbon atoms included in the first substituent are substituted with a halogen atom or a heteroatom-containing group, or a combination thereof. The halogen atom that may be included in the first substituent may include, e.g., fluorine (F), chlorine (Cl), bromine (Br), or iodine (I). The halogenated alkyl group may include a halogen atom, e.g., F, Cl, Br, or I. The heteroatom-containing group in the first substituent may include, e.g., oxygen (O), sulfur (S), or nitrogen (N). In an implementation, the heteroatom-containing group may be, e.g., —O—, —C(═O)—O—, —O—C(═O)—, —C(═O)—, —O—C(═O)—O—, —C(═O)—NH—, —NH—, —S—, —S(═O)₂—, or —S(═O)₂—O—.

In an implementation, the cycloalkyl group may include, e.g., a cyclopropyl group, a cyclopentyl group, or a cyclohexyl group.

As used herein, a term “arylalkyl group” may refer to a substituted or unsubstituted hydrocarbon aromatic group. In an implementation, the arylalkyl group may include a phenyl group, a naphthyl group, an anthracenyl group, a phenanthrenyl group, or a fluorenyl group.

In an implementation, in Formula 1, R may include, e.g., a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, or a combination thereof.

In an implementation, in Formula 1, R may include, e.g., a methoxy group, an ethoxy group, a propoxy group, a butoxy group, or a combination thereof.

In an implementation, in Formula 1, R may include a group represented by, e.g., Formula 1A.

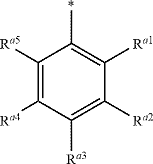

In Formula 1A, R^{a1}, R^{a2}, R^{a3}, R^{a4}, and R^{a5} may each independently be, e.g., a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof. In an implementation, R^{a1}, R^{a2}, R^{a3}, R^{a4}, and R^{a5} may be separate, or at least one of R^{a1}, R^{a2}, R^{a3}, R^{a4}, and R^{a5} may form a ring along with an atom included in Formula 1A. * denotes a bonding site.

In an implementation, in Formula 1, R may include a group represented by, e.g., Formula 1B.

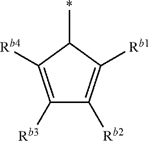

In Formula 1B, R^{b1}, R^{b2}, R^{b3}, and R^{b4} may each independently be, e.g., a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof. In an implementation, R^{b1}, R^{b2}, R^{b3}, and R^{b4} may be separate, or at least one of R^{b1}, R^{b2}, R^{b3}, and R^{b4} may form a ring along with an atom included in Formula 1B. * denotes a bonding site.

In an implementation, in Formula 1, R may be, e.g., one of the following groups.

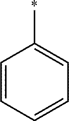 [SMILES: *c1ccccc1]

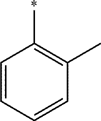 [SMILES: *c1ccccc1C]

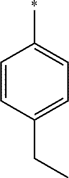 [SMILES: *c1ccc(CC)cc1]

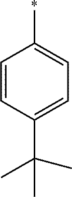 [SMILES: *c1ccc(C(C)(C)C)cc1]

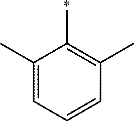

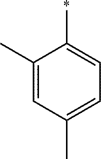 [SMILES: *c1ccc(C)cc1C]

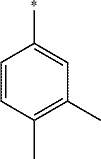 [SMILES: *c1ccc(C)c(C)c1]

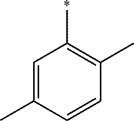

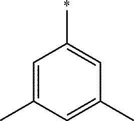

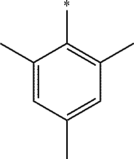

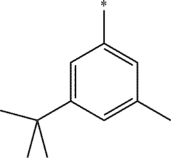 [SMILES: *c1cc(C)cc(C(C)(C)C)c1]

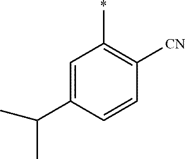 [SMILES: *c1cc(C(C)C)ccc1C#N]

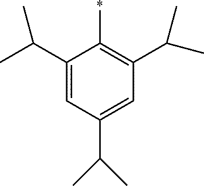 [SMILES: *c1c(C(C)C)cc(C(C)C)cc1C(C)C]

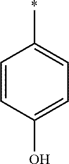 [SMILES: *c1ccc(O)cc1]

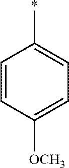 [SMILES: *c1ccc(OC)cc1]

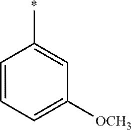 [SMILES: *c1cccc(OC)c1]

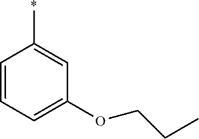 [SMILES: *c1cccc(OCCC)c1]

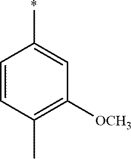 [SMILES: *c1ccc(C)c(OC)c1]

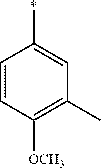 [SMILES: *c1ccc(OC)c(C)c1]

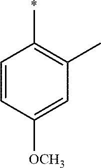 [SMILES: *c1ccc(OC)cc1C]

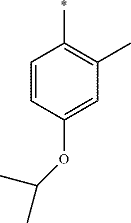 [SMILES: *c1ccc(OC(C)C)cc1C]

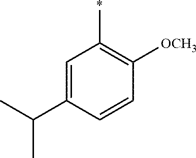 [SMILES: *c1cc(C(C)C)ccc1OC]

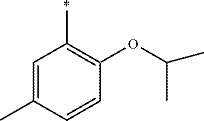 [SMILES: *c1cc(C)ccc1OC(C)C]

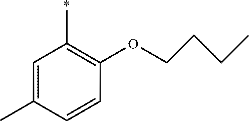 [SMILES: *c1cc(C)ccc1OCCCC]

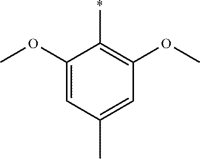

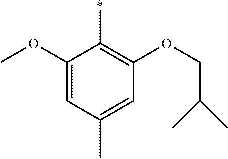 [SMILES: *c1c(OC)cc(C)cc1OCC(C)C]

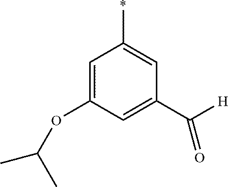 [SMILES: *c1cc(C=O)cc(OC(C)C)c1]

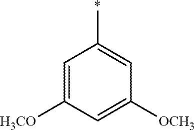 [SMILES: *c1cc(OC)cc(OC)c1]

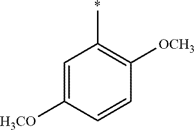 [SMILES: *c1cc(OC)ccc1OC]

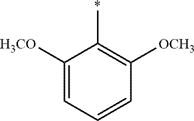 [SMILES: *c1c(OC)cccc1OC]

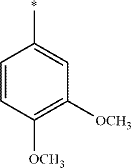 [SMILES: *c1ccc(OC)c(OC)c1]

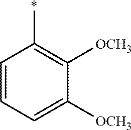 [SMILES: *c1cccc(OC)c1OC]

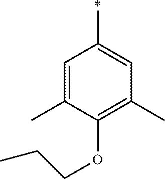 [SMILES: *c1cc(C)c(OCCC)c(C)c1]

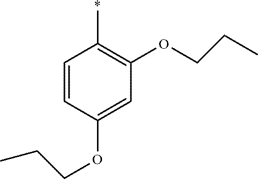 [SMILES: *c1ccc(OCCC)cc1OCCC]

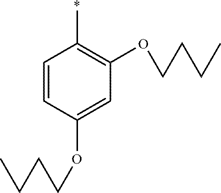 [SMILES: *c1ccc(OCCCC)cc1OCCCC]

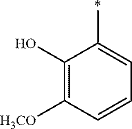 [SMILES: *c1cccc(OC)c1O]

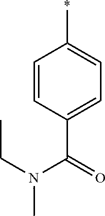 [SMILES: *c1ccc(C(=O)N(C)CC)cc1]

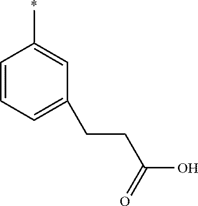 [SMILES: *c1cccc(CCC(=O)O)c1]

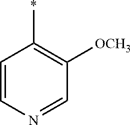 [SMILES: *c1ccncc1OC]

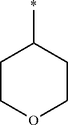 [SMILES: *C1CCOCC1]

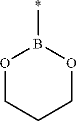 [SMILES: *B1OCCCO1]

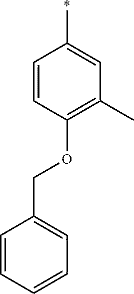 [SMILES: *c1ccc(OCc2ccccc2)c(C)c1]

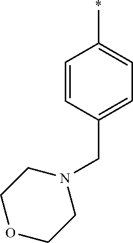 [SMILES: *c1ccc(CN2CCOCC2)cc1]

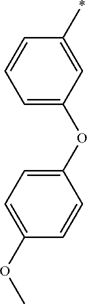 [SMILES: *c1cccc(Oc2ccc(OC)cc2)c1]

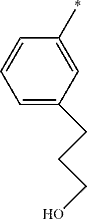 [SMILES: *c1cccc(CCCO)c1]

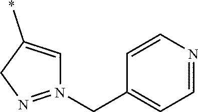

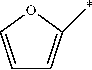 [SMILES: *c1ccco1]

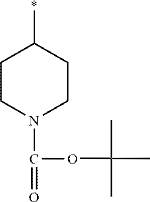 [SMILES: *C1CCN(C(=O)OC(C)(C)C)CC1]

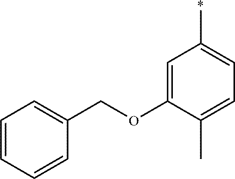 [SMILES: *c1ccc(C)c(OCc2ccccc2)c1]

In the above groups, * denotes a bonding site.

In an implementation, in Formula 1, R may include, e.g., a fused polycyclic functional group.

In an implementation, in Formula 1, R may be, e.g., one of the following groups.

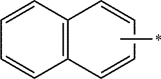

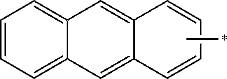

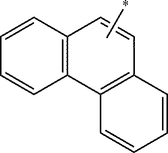

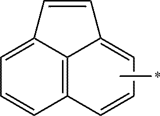

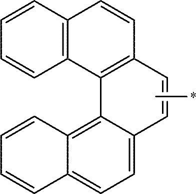

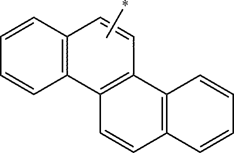

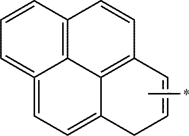

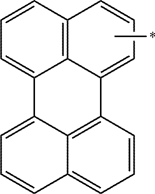

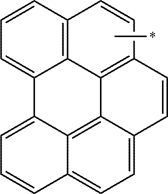

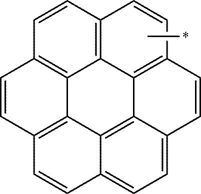

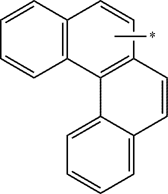

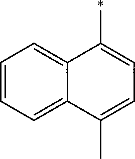 [SMILES: *c1ccc(C)c2ccccc12]

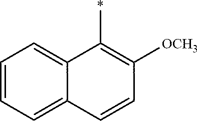 [SMILES: *c1c(OC)ccc2ccccc12]

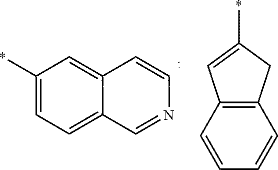

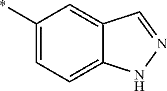 [SMILES: *c1ccc2[nH]ncc2c1]

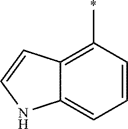 [SMILES: *c1cccc2[nH]ccc12]

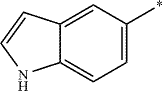 [SMILES: *c1ccc2[nH]ccc2c1]

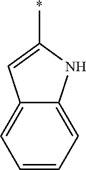 [SMILES: *c1cc2ccccc2[nH]1]

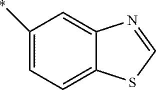 [SMILES: *c1ccc2scnc2c1]

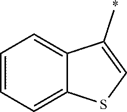 [SMILES: *c1csc2ccccc12]

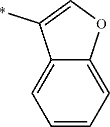 [SMILES: *c1coc2ccccc12]

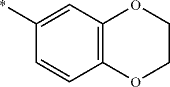 [SMILES: *c1ccc2c(c1)OCCO2]

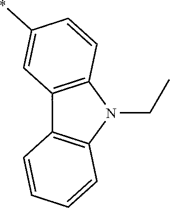 [SMILES: *c1ccc2c(c1)c1ccccc1n2CC]

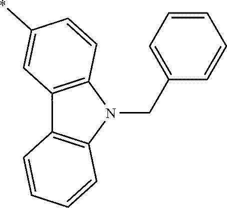 [SMILES: *c1ccc2c(c1)c1ccccc1n2Cc1ccccc1]

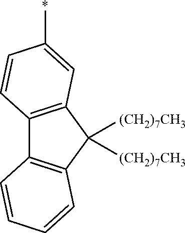

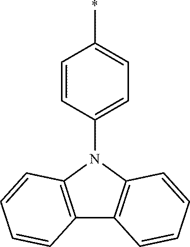 [SMILES: *c1ccc(-n2c3ccccc3c3ccccc32)cc1]

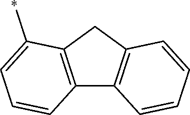 [SMILES: *c1cccc2c1Cc1ccccc1-2]

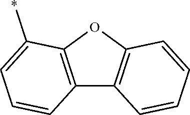 [SMILES: *c1cccc2c1oc1ccccc12]

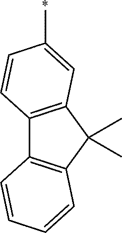 [SMILES: *c1ccc2c(c1)C(C)(C)c1ccccc1-2]

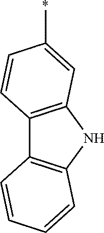 [SMILES: *c1ccc2c(c1)[nH]c1ccccc12]

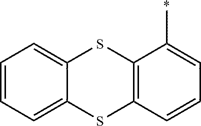 [SMILES: *c1cccc2c1Sc1ccccc1S2]

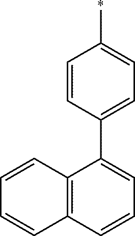 [SMILES: *c1ccc(-c2cccc3ccccc23)cc1]

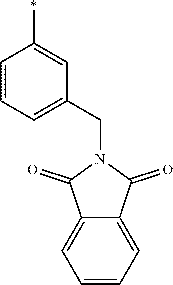 [SMILES: *c1cccc(CN2C(=O)c3ccccc3C2=O)c1]

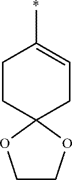 [SMILES: *C1=CCC2(CC1)OCCO2]

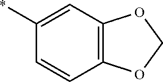 [SMILES: *c1ccc2c(c1)OCO2]

In the above groups, * denotes a bonding site.

A hardmask-forming compound according to other embodiments may be represented by Formula 2 (e.g., may include a moiety or repeating unit represented by Formula 2).

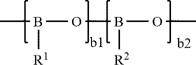

In Formula 2, R¹ and R² may have different structures. In an implementation, R¹ and R² may each independently be or include, e.g., a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof. In an implementation, R¹ and R² may each be pendent, or at least one of R¹ and R² may form a ring along with a boron atom of Formula 2. In an implementation, b1 and b2 may each independently be, e.g., an integer ranging from 1 to 50. In an implementation, b1/(b1+b2) may range from, e.g., 0.1 to 0.9.

In Formula 2, R¹ and R² may be defined the same as R of Formula 1, described above.

A hardmask-forming compound according to other embodiments may be represented by Formula 2A (e.g., may include a moiety or repeating unit represented by Formula 2A).

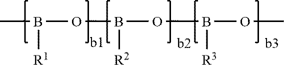

In Formula 2A, R¹, R², and R³ may have different structures. In an implementation, R¹, R², and R³ may each independently be or include, e.g., a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof. In an implementation, R¹, R², and R³ may be separate, or at least one of R¹, R², and R³ may form a ring along with a boron atom of Formula 2A. In an implementation, b1, b2, and b3 may each independently be, e.g., an integer ranging from 1 to 50. In an implementation, b1/(b1+b2+b3), b2/(b1+b2+b3), and b3/(b1+b2+b3) may each independently be, e.g., in a range of 0.1 to 0.7.

In Formula 2A, R¹, R², and R³ may each be defined the same as R of Formula 1, described above.

A hardmask-forming compound according to other embodiments may by represented by Formula 2B (e.g., may include a moiety or repeating unit represented by Formula 2B).

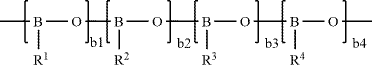

In Formula 2B, R¹, R², R³, and R⁴ may have different structures. In an implementation, R¹, R², R³, and R⁴ may each independently be or include, e.g., a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof. In an implementation, R¹, R², R³, and R⁴ may be separate, or at least one of R¹, R², R³, and R⁴ may form a ring along with a boron atom of Formula 2B.

b1, b2, b3, and b4 may each independent be, e.g., an integer ranging from 1 to 50.

b1/(b1+b2+b3+b4), b2/(b1+b2+b3+b4), b3/(b1+b2+b3+b4), and b4/(b1+b2+b3+b4) may each independently be, e.g., in a range of 0.1 to 0.7.

In Formula 2B, R¹, R², R³, and R⁴ may be defined the same as R of Formula 1, described above.

In an implementation, the hardmask-forming compounds may be polymerized products of boric acid including an organic protecting group bonded to a boron atom and may include two, three, and four repeating units, as given in Formulas 2, 2A, and 2B. In an implementation, a hardmask-forming compound may further include at least one additional repeating unit in addition to the repeating units represented by Formula 2, Formula 2A, or Formula 2B, and the at least one additional repeating unit may have the same structure as in Formula 1. In the hardmask-forming compound according to the embodiments, the number of repeating units may be a suitable number.

A hardmask composition according to embodiments may include the hardmask-forming compound according to the embodiments described above and a solvent. In an implementation, the hardmask composition according to the embodiments may include a hardmask-forming compound having the structure of Formula 1 and a solvent. In an implementation, the hardmask composition according to the embodiments may include a hardmask-forming compound having any a structure of Formula 2, Formula 2A, or Formula 2B and a solvent.

In the hardmask composition according to the embodiments, the solvent may include a suitable material having solubility or dispersibility in the hardmask-forming compound. In an implementation, the solvent may include, e.g., deionized water (DIW), an organic solvent, an alcoholic solvent, or a combination thereof. In an implementation, the solvent may include, e.g., a mixture of DIW and an organic solvent.

In an implementation, the solvent may include DIW; alcohols such as methanol, ethanol, isopropanol, propanol, butanol, or terpineol; amides such as dimethyl formamide (DMF) or dimethyl acetoamide; pyrrolidones such as N-methyl-2-pyrrolidone or N-ethylpyrrolidone; hydroxy esters such as dimethyl sulfoxide, γ-butyrolactone, methyl lactate, ethyl lactate, methyl β-methoxyisobutyrate, or methyl α-hydroxyisobutyrate; glycol derivatives such as propyleneglycol, propyleneglycol diacetate, diethyleneglycol, diethyleneglycol butylether, tri(ethyleneglycol)monomethylether, propyleneglycol monomethylether, or propyleneglycol monomethylether acetate; organic halides such as dichloroethane, dichlorobenzene, or trichloroethane; nitro compounds, such as nitromethane or nitroethane; nitrile compounds such as acetonitrile or benzonitrile; or a combination thereof.

In the hardmask composition according to the embodiments, a content of the solvent may be selected in an appropriate range considering a desired viscosity of the hardmask composition. In an implementation, the amount of the solvent in the hardmask composition may be adjusted so that a solid content of the hardmask composition may be in a range of about 3% to about 20% by weight.

In an implementation, the hardmask composition according to the embodiments may further include a surfactant.

In an implementation, the surfactant may include, e.g., fluoroalkylbenzenesulfonate, fluoroalkyl carboxylate, fluoroalkylpolyoxyethyleneether, fluoroalkylammonium iodide, fluoroalkylbetaine, fluoroalkylsulfonate, diglycerin tetrakis (fluoroalkyl polyoxyethyleneether), fluoroalkyl trimethylammonium salt, fluoroalkylaminosulfonate, polyoxyethylenenonylphenylether, polyoxyethyleneoctylphenylether, polyoxyethylenealkylether, polyoxyethylenelaurylether, polyoxyethylene oleylether, polyoxyethylene tridecylether, polyoxyethylene cetylether, polyoxyethylene stearylether, polyoxyethylenelaurate, polyoxyethylene oleate, polyoxyethylenestearate, polyoxyethylenelaurylamine, sorbitan laurate, sorbitan palmitate, sorbitan stearate, sorbitan oleate, sorbitan fatty acid ester, polyoxyethylene sorbitanlaurate, polyoxyethylene sorbitanpalmitate, polyoxyethylenesorbitanstearate, polyoxyethylenesorbitan oleate, polyoxyethylene naphthylether, alkylbenzenesulfonate, or alkyldiphenyletherdisulfonate. In an implementation, the surfactant may be included at a content of, e.g., about 0.001% to about 0.1% by weight, based on the total weight of the hardmask composition. By including the surfactant in the hardmask composition, the solubility of the hardmask-forming compound in the hardmask composition may be improved.

In a method of manufacturing an integrated circuit (IC) device according to embodiments, a target structure to be etched may be coated with a hardmask composition including a hardmask-forming compound to form a hardmask coating layer, and the hardmask coating layer may be annealed to form a boron-containing hardmask layer. As the boron-containing hardmask layer is being formed by annealing the hardmask coating layer, in the hardmask-forming compound included in the hardmask coating layer, the organic protecting group (e.g., R of Formula 1 or at least one of R¹ and R² of Formula 2) may be separated from a boron atom, and an oxygen atom may be bonded to the boron atom in place of the organic protecting group. As a result, the boron-containing hardmask layer including a network system may be obtained. The network system may have a cross-linked network structure obtained due to a —B—O— bond included in the hardmask-forming compound and a new —B—O— bond, which is formed by the oxygen atom bonded to the boron atom instead of the organic protecting group.

In an implementation, when a boron-containing hardmask layer is formed by annealing the hardmask coating layer obtained from a hardmask composition including the hardmask-forming compound having the structure of Formula 1, the boron-containing hardmask layer may include a moiety of Formula 1C and a moiety of Formula 1D.

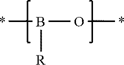

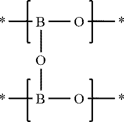

Accordingly, a boron content per unit volume in the boron-containing hardmask layer may increase, and thus, etching resistance of an etching mask structure including the boron-containing hardmask layer may be improved. In addition, in the etching mask structure, defects (e.g., peeling-off) may not occur between the boron-containing hardmask layer and other hardmask layers adjacent thereto, and excellent adhesion characteristics may be provided therebetween.

In an implementation, in a boron-containing hardmask layer obtained from a hardmask composition including at least one compound of Formula 1, Formula 2, Formula 2A, or Formula 2B, according to the embodiments, a content of boron atoms may be in a range of, e.g., about 5 atomic percent (at%) to about 50 at%, or a range of about 10 at% to about 35 at% (based on a total number of atoms in the compound). If the content of boron atoms in the boron-containing hardmask layer were to be excessively low, it could be difficult to obtain a sufficient etching resistance during an etching process using the hardmask coating layer as an etch mask. If the content of boron atoms in the boron-containing hardmask layer were to be excessively high, the uniformity of the boron content in the boron-containing hardmask layer could deteriorate, and adhesion characteristics between the boron-containing hardmask layer and other hardmask layers adjacent thereto could deteriorate, and thus, undesired peeling-off could occur.

In an implementation, in the boron-containing hardmask layer obtained from the hardmask composition including the hardmask-forming compound of Formula 1, Formula 2, Formula 2A, or Formula 2B, according to the embodiments, a content of oxygen atoms may be, e.g., in a range of about 5 at% to about 75 at%, or a range of about 10 at% to about 70 at%. By selecting the content of oxygen atoms in the boron-containing hardmask layer in the above-described range, adhesion characteristics between the boron-containing hardmask layer and other hardmask layers adjacent thereto may be improved.

Hereinafter, methods of manufacturing IC devices, according to embodiments, will be described with reference to the accompanying drawings.

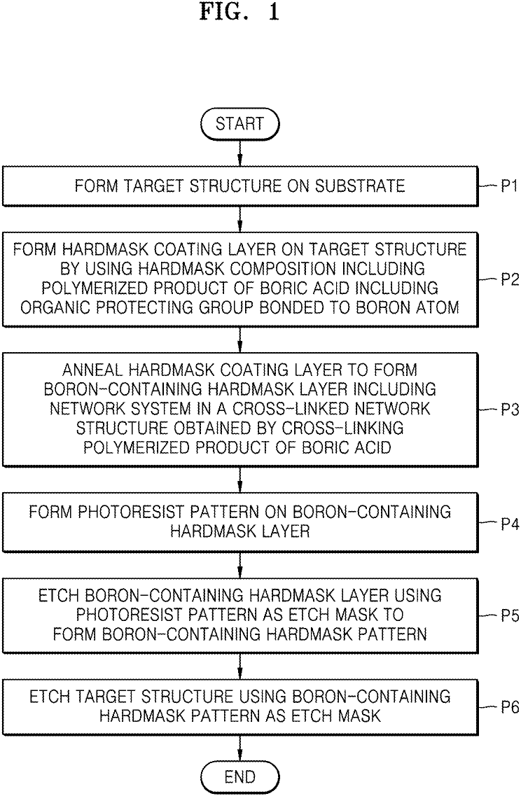

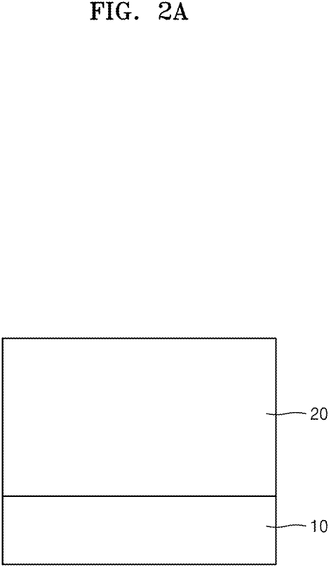

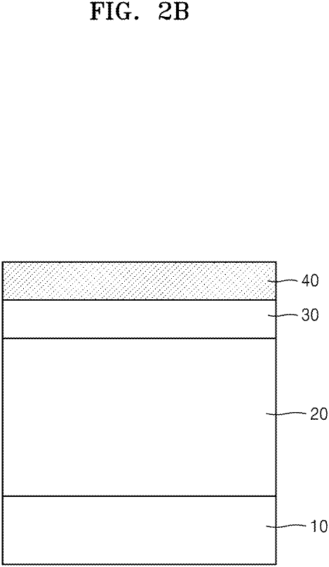

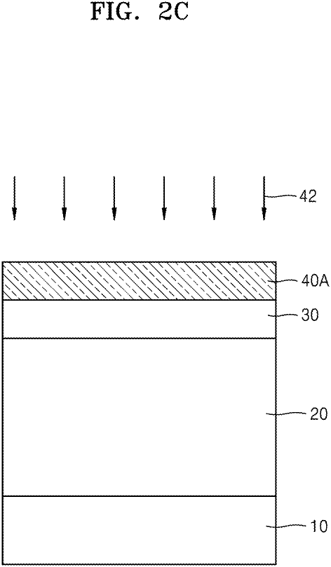

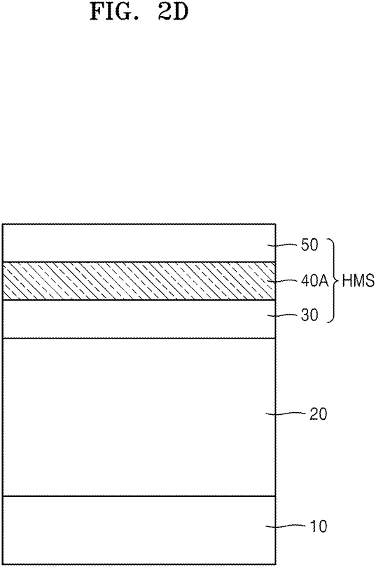

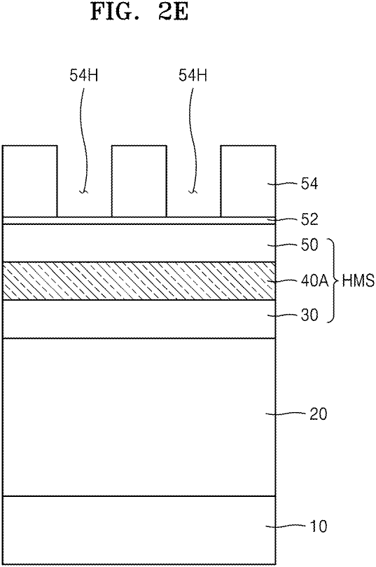

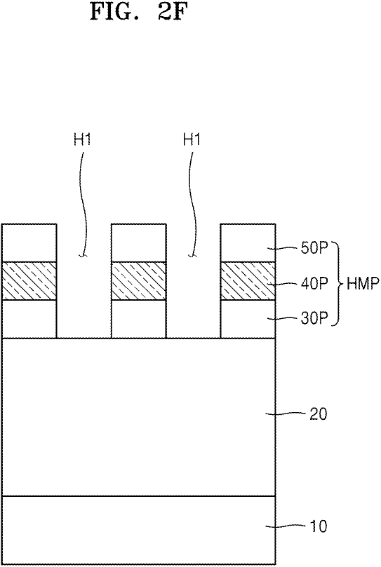

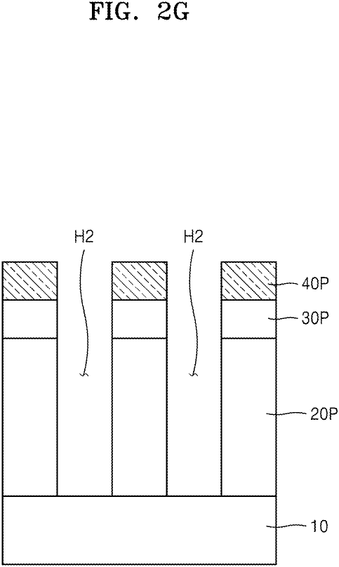

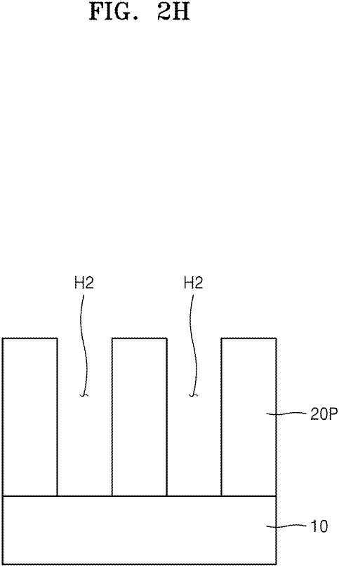

FIG. 1 is a flowchart of a method of manufacturing an IC device according to embodiments. FIGS. 2A to 2H are cross-sectional views of stages in a method of manufacturing an IC device, according to embodiments. The method of manufacturing the IC device, according to the embodiments, will be described with reference to FIGS. 1 and 2A to 2H.

Referring to FIGS. 1 and 2A, in process P1, a target structure 20 may be formed on a substrate 10.

When the term “substrate” is used herein, it should be understood as either the substrate itself or a stack structure including the substrate and a predetermined layer or film formed on a surface of the substrate. When the expression “a surface of a substrate” is used herein, it should be understood as either as an exposed surface of the substrate itself or an outer surface of a predetermined layer or film formed on the substrate. The substrate 10 may include a semiconductor substrate. In an implementation, the substrate 10 may include an element semiconductor, e.g., silicon (Si) or germanium (Ge). In an implementation, the substrate 10 may include a compound semiconductor, e.g., silicon germanium (SiGe), silicon carbide (SiC), gallium arsenide (GaAs), indium arsenide (InAs), or indium arsenide (InP). In an implementation, the substrate 10 may have a silicon-on-insulator (SOI) structure. The substrate 10 may include a conductive region, e.g., a doped well or a doped structure. In an implementation, the substrate 10 may include a transparent substrate.

The target structure 20 may include a semiconductor material, a conductive material, an insulating material, or a combination thereof.

In an implementation, the target structure 20 may include an insulating structure including at least one insulating film. The at least one insulating film may include a silicon oxide film, a silicon nitride film, a silicon oxynitride film, a low-k dielectric film having a lower dielectric constant than the silicon oxide film, or a combination thereof. In an implementation, the target structure 20 may include, e.g., tetraethylorthosilicate (TEOS), plasma-enhanced tetraethylorthosilicate (PE-TEOS), O₃-TEOS, undoped silicate glass (USG), phosphosilicate glass (PSG), borosilicate glass (BSG), borophosphosilicate glass (BPSG), fluoride silicate glass (FSG), spin on glass (SOG), or a combination thereof.

In an implementation, the target structure 20 may include a semiconductor film. In an implementation, the target structure 20 may include, e.g., crystalline silicon, amorphous silicon, doped silicon, SiGe, SiC, or a combination thereof.

In an implementation, the target structure 20 may include at least one conductive film. In an implementation, the target structure 20 may include, e.g., a doped a polysilicon film, a metal silicide film, a metal film, a metal nitride film, or a combination thereof.

Referring to FIGS. 1 and 2B, in process P2, a lower hardmask layer 30 may be formed on the target structure 20, and a hardmask coating layer 40 containing boron may be formed on the lower hardmask layer 30.

In an implementation, the lower hardmask layer 30 may include a silicon-containing film. In an implementation, the lower hardmask layer 30 may include an amorphous silicon film, a polysilicon film, a silicon oxide film, a silicon nitride film, a silicon oxynitride film, or a combination thereof. After the hardmask coating layer 40 is formed, a bottom surface of the hardmask coating layer 40 may be in contact (e.g., direct contact) with a top surface of the lower hardmask layer 30.

In an implementation, to form the hardmask coating layer 40, a hardmask composition including a polymerized product of boric acid including an organic protecting group bonded to a boron atom may be used. In an implementation, the hardmask composition may include the hardmask composition according to the embodiments described above. The hardmask composition may include the hardmask-forming compound according to the embodiments described above and a solvent. The hardmask composition may include the hardmask-forming compound having the structure of Formula 1 and a solvent. In an implementation, the hardmask composition may include the hardmask-forming compound having the structure of Formula 2, Formula 2A, or Formula 2B and a solvent. A detailed configuration of the hardmask composition may be understood with reference to the above description.

In an implementation, to form the hardmask coating layer 40, the top surface of the lower hardmask layer 30 may be spin-coated with the hardmask composition according to the embodiments.

Referring to FIGS. 1 and 2C, in process P3, the hardmask coating layer 40 may be annealed (refer to 42) in the resultant structure of FIG. 2B, and thus, a boron-containing hardmask layer 40A including a network system may be formed by cross-linking the polymerized product of the boric acid.

In an implementation, the annealing 42 of the hardmask coating layer 40 may be performed at a temperature of, e.g., about 100° C. to about 600° C. In an implementation, the annealing 42 of the hardmask coating layer 40 may be performed under an inert gas atmosphere and/or a vacuum. The inert gas atmosphere may include, e.g., nitrogen gas, argon (Ar) gas, or a combination thereof.

In an implementation, the annealing 42 of the hardmask coating layer 40 may be performed by using, e.g., induction heating, radiant heat, a laser, infrared (IR) light, microwave, plasma, ultraviolet (UV) light, or surface plasmon heating.

During the annealing 42 of the hardmask coating layer 40, the hardmask coating layer 40 may be desolventized. During the annealing 42 of the boron-containing hardmask layer 40A, in the polymerized product (e.g., a compound having the structure of Formula 1 or a compound having the structure of Formula 2) of the boric acid included in the hardmask coating layer 40, the organic protecting group (e.g., R of Formula 1 or at least one of R¹ and R² of Formula 2) may be separated from the boron atom, and an oxygen atom may be bonded to the boron atom in place of the organic protecting group. As a result, the boron-containing hardmask layer 40A including the network system cross-linked in the network structure may be obtained due to a —B—O— bond included in the polymerized product of the boric acid and a new —B—O— bond, which is formed by the oxygen atom bonded to the boron atom instead of the organic protecting group.

In an implementation, the boron-containing hardmask layer 40A may include the structure of Formula 1C and the structure of Formula 1D as described above. Accordingly, a boron content per unit volume in the boron-containing hardmask layer 40A may increase, and etching resistance of an etching mask structure including the boron-containing hardmask layer 40A may be improved. In addition, adhesion characteristics between the top surface of the lower hardmask layer 30 and a bottom surface of the boron-containing hardmask layer 40A may be improved. Thus, the occurrence of problems (e.g., peeling-off of the boron-containing hardmask layer 40A from the lower hardmask layer 30) may be inhibited during subsequent processes.

Referring to FIG. 2D, an upper hardmask layer 50 may be formed on the boron-containing hardmask layer 40A.

The lower hardmask layer 30, the boron-containing hardmask layer 40A, and the upper hardmask layer 50 may constitute a hardmask structure HMS. The upper hardmask layer 50 may include a silicon-containing film. In an implementation, the upper hardmask layer 50 may include an amorphous silicon film, a polysilicon film, a silicon oxide film, a silicon nitride film, a silicon oxynitride film, or a combination thereof. In an implementation, a constituent material of the upper hardmask layer 50 may be different from a constituent material of the lower hardmask layer 30. In an implementation, the constituent material of the upper hardmask layer 50 may be the same as the constituent material of the lower hardmask layer 30.

After the upper hardmask layer 50 is formed, a bottom surface of the upper hardmask layer 50 may be in contact (e.g., direct contact) with a top surface of the boron-containing hardmask layer 40A. As described above with reference to FIG. 2C, the boron-containing hardmask layer 40A may have a relatively high boron content per unit volume and, thus, may have excellent etching resistance. In addition, adhesion characteristics between the top surface of the boron-containing hardmask layer 40A and a bottom surface of the upper hardmask layer 50 may be improved, and thus, the occurrence of problems (the peeling-off of the boron-containing hardmask layer 40A from the lower hardmask layer 30) may be inhibited during subsequent processes. Accordingly, the hardmask structure HMS may obtain excellent etching resistance.

In an implementation, one of the lower hardmask layer 30 or the upper hardmask layer 50 may be omitted from the hardmask structure HMS.

Referring to FIGS. 1 and 2E, in process P4, a developable bottom anti-reflective coating (DBARC) film 52 and a photoresist film may be sequentially formed on the hardmask structure HMS, a partial region of the photoresist film may be exposed, and the photoresist film may be developed to form a photoresist pattern 54. The photoresist pattern 54 may include a plurality of holes 54H.

The DBARC film 52 may help control diffuse reflection of light from a light source used during an exposure process for manufacturing an IC device or absorb reflected light from underlying films. In an implementation, the DBARC film 52 may include an organic anti-reflective coating (ARC) material for a krypton fluoride (KrF) excimer laser, an argon fluoride (ArF) excimer laser, or other suitable light sources. In an implementation, the DBARC film 52 may include an organic component having a light-absorbing structure. The light-absorbing structure may include, e.g., at least one benzene ring or a hydrocarbon compound in which benzene rings are fused. In an implementation, the DBARC film 52 may be formed to a thickness of, e.g., about 20 nm to about 100 nm. In an implementation, the DBARC film 52 may be omitted.

To form the photoresist pattern 54, a photoresist film may be formed using a photoresist composition including a chemically amplified polymer, a photo-labile compound, and a solvent. In an implementation, the photoresist film may include a resist material for extreme ultraviolet (EUV) (13.5 nm). In an implementation, the photoresist film may include resist for F₂ excimer laser (157 nm), resist for ArF excimer laser (193 nm), or resist for KrF excimer laser (248 nm). The photoresist film may include positive-type photoresist or negative-type photoresist.

In an implementation, to form a photoresist film including the positive-type photoresist, a photoresist composition including a photosensitive polymer having an acid-labile group, a potential acid, and a solvent may be spin-coated on the feature layer.

In an implementation, the photosensitive polymer may include a (meth)acrylate-based polymer. The (meth)acrylate-based polymer may include an aliphatic (meth)acrylate-based polymer. In an implementation, the photosensitive polymer may include polymethylmethacrylate (PMMA), poly(t-butylmethacrylate), poly(methacrylic acid), poly(norbornylmethacrylate), a binary or ternary copolymer of repeating units of the (meth)acrylate-based polymers, or a mixture thereof. The above-described examples of the photosensitive polymer may be substituted with various acid-labile protecting groups. The protecting group may include tert-butoxycarbonyl (t-BOC), tetrahydropyranyl, trimethylsilyl, phenoxyethyl, cyclohexenyl, tert-butoxycarbonylmethyl, tert-butyl, adamantyl, or a norbornyl group.

In an implementation, the potential acid may include a photoacid generator (PAG), a thermoacid generator (TAG), or a combination thereof. In an implementation, the PAG may include a material that generates acid when exposed to EUV light (13.5 nm), an F₂ excimer laser (157 nm), an ArF excimer laser (193 nm), or a KrF excimer laser (248 nm). The PAG may include onium salts, a halogen compound, nitrobenzyl esters, alkylsulfonates, diazonaphthoquinones, iminosulfonates, disulfones, diazomethanes, sulfonyloxyketones, or the like.

In an exposure process for exposing the partial region of the photoresist film, EUV light (13.5 nm), a F₂ excimer laser (157 nm), an ArF excimer laser (193 nm), or a KrF excimer laser (248 nm) may be used.

Referring to FIGS. 1 and 2F, in process P5, at least a portion of the hardmask structure HMS may be etched using the photoresist pattern 54 as an etch mask in the resultant structure of FIG. 2E, and thus, a hardmask structure pattern HMP may be formed. The hardmask structure pattern HMP may include a plurality of holes H1.

The hardmask structure pattern HMP may include a lower hardmask pattern 30P, a boron-containing hardmask pattern 40P, and an upper hardmask pattern 50P, which are sequentially stacked on the target structure 20.

To form the hardmask structure pattern HMP, the upper hardmask layer 50, the boron-containing hardmask layer 40A, and the lower hardmask layer 30 may be sequentially etched using the photoresist pattern 54 as an etch mask, and thus, the lower hardmask pattern 30P, the boron-containing hardmask pattern 40P, and the upper hardmask pattern 50P may be formed. After the hardmask structure pattern HMP is formed, unnecessary films on the hardmask structure pattern HMP may be removed.

During the formation of the hardmask structure pattern HMP, a state of adhesion of the lower hardmask layer 30 with the boron-containing hardmask layer 40A and a state of adhesion of the boron-containing hardmask layer 40A with the upper hardmask layer 50 may be reliably maintained, and thus, the occurrence of problems (e.g., peeling-off) therebetween may be prevented.

Referring to FIGS. 1 and 2G, in process P6, the target structure 20 may be anisotropically etched using the hardmask structure pattern HMP as an etch mask in the resultant structure of FIG. 2F. Thus, a target pattern 20P having a plurality of vertical holes H2 may be formed to pass through at least a portion of the target structure 20.

To anisotropically etch the target structure 20, an etch gas mixture may be supplied into a reaction chamber in which the substrate 10 is loaded, in a plasma atmosphere. In an implementation, when the target structure 20 includes a silicon oxide film, a silicon nitride film, or a combination thereof, the etch gas mixture may include a fluorinated hydrocarbon compound, a reactive gas, and a carrier gas. In an implementation, the fluorinated hydrocarbon compound may include, e.g., CF₄, C₂F₆, C₄F₆, C₄F₈, CHF₃, CH₂F₂, CH₃F, C₃H₂F₆, C₄H₂F₆, C₄F₆, or a mixture thereof. The etch gas mixture may further include a fluorine-containing compound, e.g., NF₃, HBr, and CH₃F. The reactive gas may include, e.g., O₂, CO, CO₂, NO, NO₂, N₂O, H₂, NH₃, HF, SO₂, CS₂, COS, CF₃I, C₂F₃I, C₂F₅I, or a mixture thereof. The carrier gas may include, e.g., argon (Ar), xenon (Xe), helium (He), neon (Ne), nitrogen (N₂), krypton (Kr), or a mixture thereof.

A portion of the hardmask structure pattern HMP may be consumed during the anisotropic etching process for forming the plurality of vertical holes H2.

During the etching of the target structure 20, a state of adhesion of the lower hardmask pattern 30P with the boron-containing hardmask pattern 40P and a state of adhesion of the boron-containing hardmask pattern 40P with the upper hardmask pattern 50P may be reliably maintained in the hardmask structure pattern HMP. Furthermore, because the boron-containing hardmask pattern 40P includes a network system cross-linked in a network structure due to a —B—O— bond, the hardmask structure pattern HMP may provide excellent etching resistance due to the boron-containing hardmask pattern 40P during the etching of the target structure 20. Accordingly, even when the plurality of vertical holes H2 has a relatively high aspect ratio, the plurality of vertical holes H2 may obtain a desired vertical profile and a desired etch rate.

Referring to FIG. 2H, unnecessary films remaining on the target pattern 20P may be removed from the resultant structure of FIG. 2G.

Thereafter, a plurality of vertical plugs may be formed to fill the plurality of vertical holes H2 that pass through the target pattern 20P. In an implementation, each of the vertical plugs may be a lower electrode of a capacitor of dynamic random access memory (DRAM). In an implementation, the vertical plug may constitute a channel structure, a dummy channel structure, a word line cut structure, a through electrode, or a memory cell contact, which is in a memory cell array structure of a vertical NAND flash memory (hereinafter, referred to as “VNAND”).

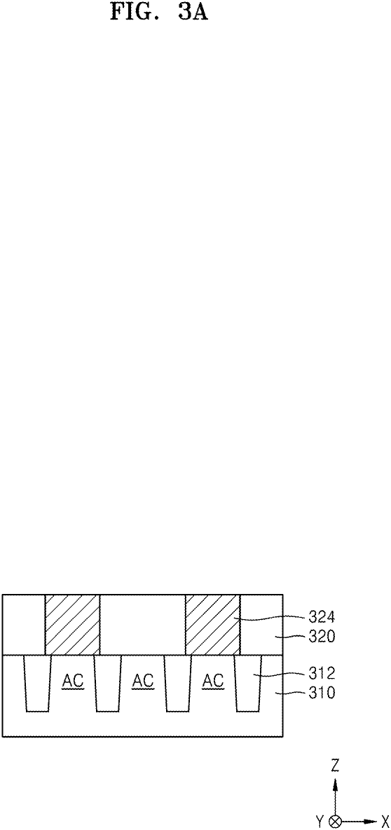

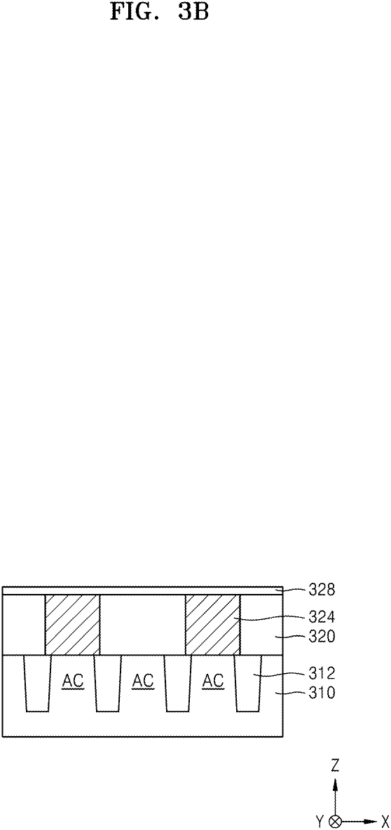

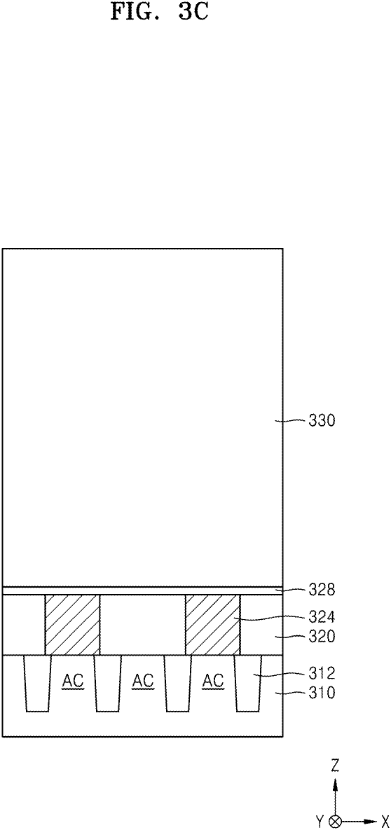

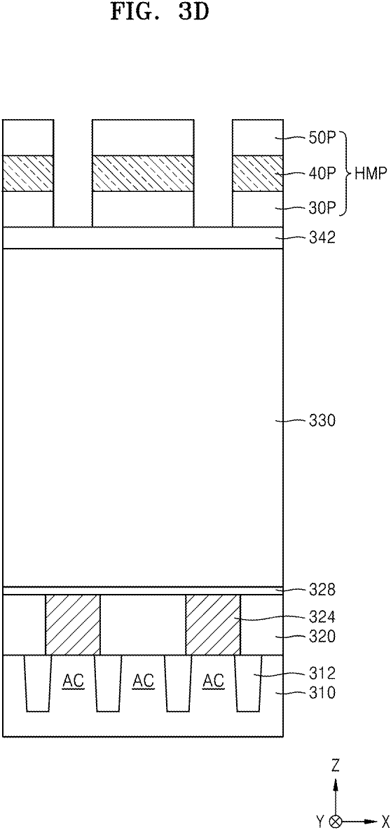

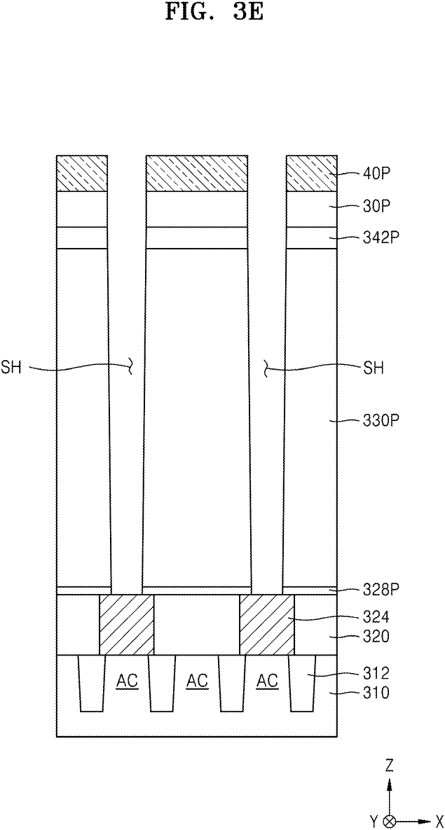

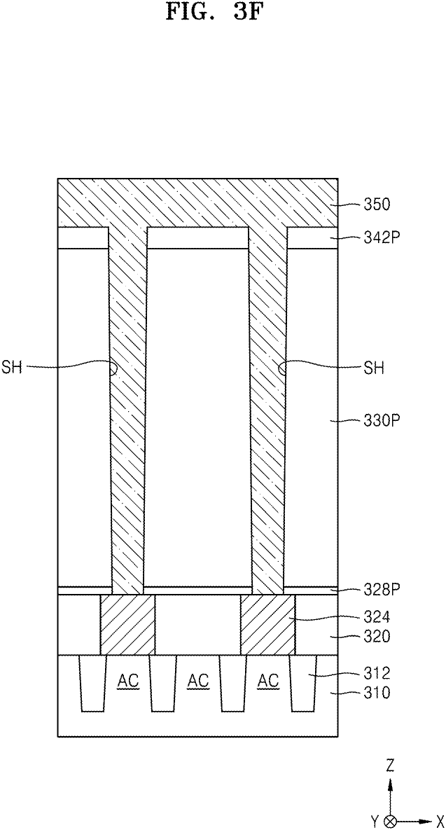

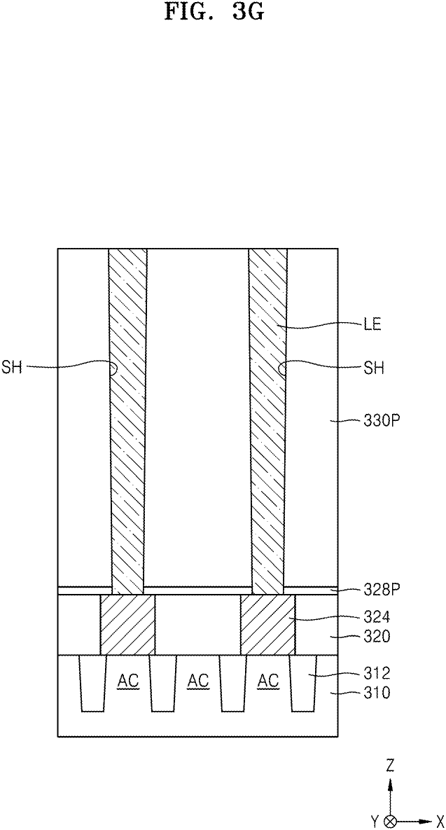

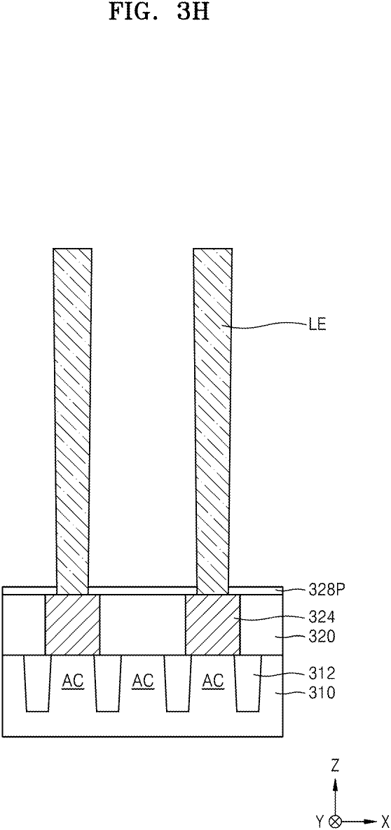

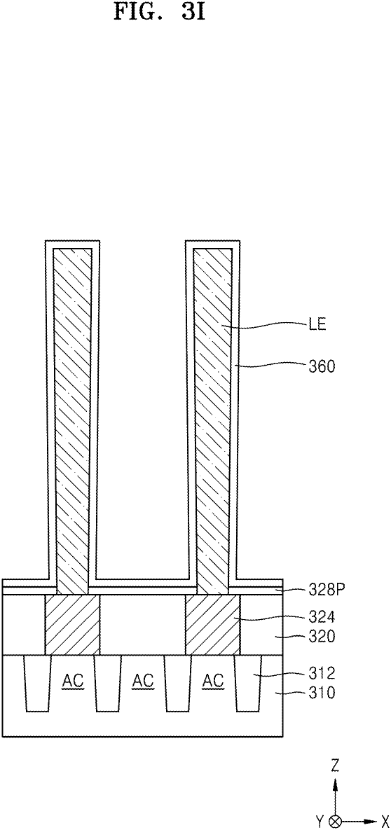

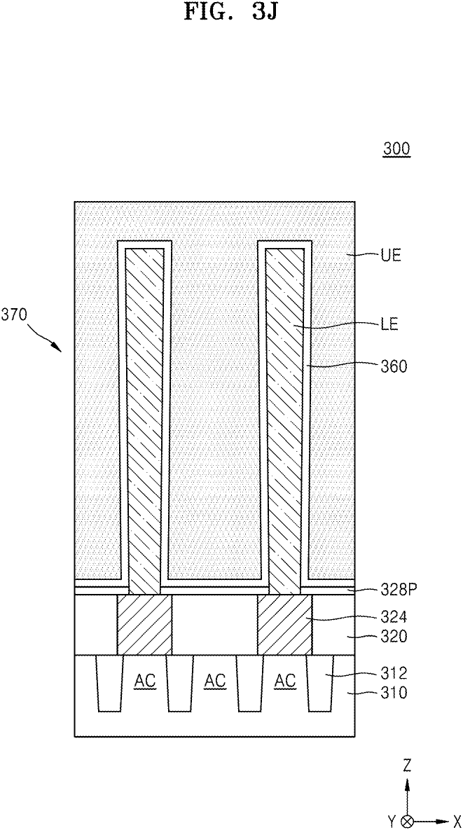

FIGS. 3A to 3J are cross-sectional views of stages in a method of manufacturing an IC device (refer to 300 in FIG. 3J), according to embodiments. An example method of manufacturing the IC device 300 including a capacitor of DRAM will be described with reference to FIGS. 3A to 3J

Referring to FIG. 3A, an interlayer dielectric 320 may be formed on a substrate 310 including a plurality of active regions AC. Thereafter, a plurality of conductive regions 324 may be formed to pass through the interlayer dielectric 320 and be connected to a plurality of active regions AC.

The substrate 310 may include an element semiconductor, e.g., silicon or germanium, or a compound semiconductor, e.g., SiGe, SiC, GaAs, InAs, or InP. The substrate 310 may include a conductive region, e.g., a doped well or a doped structure. The plurality of active regions AC may be defined by a plurality of device isolation regions 312 formed in the substrate 310. The device isolation regions 312 may include a silicon oxide film, a silicon nitride film, silicon oxynitride film, or a combination thereof. The interlayer dielectric 320 may include a silicon oxide film. The plurality of conductive regions 324 may be connected to one terminal of a switching device (e.g., a field-effect transistor) formed on the substrate 310. The plurality of conductive regions 324 may include polysilicon, a metal, a conductive metal nitride, a metal silicide, or a combination thereof.

Referring to FIG. 3B, an insulating layer 328 may be formed to cover the interlayer dielectric 320 and the plurality of conductive regions 324. The insulating layer 328 may be used as an etch stop layer. The insulating layer 328 may include an insulating material having an etch selectivity with respect to the interlayer dielectric 320 and a mold film (refer to 330 in FIG. 3C) formed in a subsequent process. The insulating layer 328 may include silicon nitride, silicon oxynitride, or a combination thereof.

Referring to FIG. 3C, the mold film 330 may be formed on the insulating layer 328.

The mold film 330 may include an oxide film. In an implementation, the mold film 330 may include an oxide film, such as a BPSG film, a PSG film, or an USG film. To form the mold film 330, a thermal chemical vapor deposition (CVD) process or a plasma-enhanced CVD (PECVD) process may be used. The mold film 330 may be formed to a thickness of, e.g., about 1,000 Å to about 20,000 Å. In an implementation, the mold film 330 may include a support film. The support film may be formed using a material having an etch selectivity with respect to the mold film 330. The support film may include a material having a relatively low etch rate with respect to an etch atmosphere (e.g., an etchant including ammonium fluoride (NH₄F), hydrofluoric acid (HF), and water), which is used when the mold film 330 is removed in a subsequent process. In an implementation, the support film may include silicon nitride, silicon carbonitride, tantalum oxide, titanium oxide, or a combination thereof.

Referring to FIG. 3D, a sacrificial film 342 and a hardmask structure pattern HMP may be sequentially formed on the mold film 330.

The sacrificial film 342 may include an oxide film. The hardmask structure pattern HMP may include a lower hardmask pattern 30P, a boron-containing hardmask pattern 40P,and an upper hardmask pattern 50P, which are sequentially stacked on the sacrificial film 342. The hardmask structure pattern HMP may be formed using the processes described with reference to FIGS. 2B to 2F.

A region in which a lower electrode of a capacitor will be formed may be defined by the hardmask structure pattern HMP. The mold film 330 and the sacrificial film 342 may constitute a target structure to be etched.

Referring to FIG. 3E, a target structure including the sacrificial film 342 and the mold film 330 may be anisotropically etched by using the hardmask structure pattern HMP as an etch mask and using the insulating layer 328 as an etch stop layer to form a plurality of vertical holes SH, and a sacrificial pattern 342P and a mold pattern 330P may be formed to define the plurality of vertical holes SH. During the formation of the plurality of vertical holes SH, the insulating layer 328 may also be etched due to an over-etching process to form an insulating pattern 328P exposing the plurality of conductive regions 324.

The plurality of vertical holes SH may be formed using the same method as the process of forming the plurality of vertical holes H2, which has been described with reference to FIG. 2G. The anisotropic etching process for forming the plurality of vertical holes SH may be performed in a plasma atmosphere. During the anisotropic etching process for forming the plurality of vertical holes SH, the hardmask structure pattern HMP may be partially consumed.

During the anisotropic etching process for forming the plurality of vertical holes SH, the sacrificial film 342 and the mold film 330 may be etched while a state of adhesion of the lower hardmask pattern 30P with the boron-containing hardmask pattern 40P and a state of adhesion of the boron-containing hardmask pattern 40P with the upper hardmask pattern 50P are reliably maintained in the hardmask structure pattern HMP. In addition, because the boron-containing hardmask pattern 40P includes a network system cross-linked in a network structure due to a —B—O— bond, while the sacrificial film 342 and the mold film 330 are being etched to form the plurality of vertical holes SH, the hardmask structure pattern HMP may provide excellent etching resistance due to the boron-containing hardmask pattern 40P. Accordingly, even when the plurality of vertical holes SH have a relatively high aspect ratio, the plurality of vertical holes SH may obtain a desired vertical profile and a desired etch rate.

Referring to FIG. 3F, residues of the hardmask structure pattern HMP may be removed from the resultant structure of FIG. 3E, and a conductive film 350 for forming lower electrodes may be formed to fill the plurality of vertical holes SH and cover an exposed surface of the sacrificial pattern 342P.

The conductive film 350 for forming lower electrodes may include a doped semiconductor, a conductive metal nitride, a metal, a metal silicide, a conductive oxide, or a combination thereof. In an implementation, the conductive film 350 for forming lower electrodes may include a doped semiconductor, a conductive metal nitride, a metal, a metal silicide, a conductive oxide, or a combination thereof. In an implementation, the conductive film 350 for forming lower electrodes may include niobium nitride (NbN), titanium nitride (TiN), titanium aluminum nitride (TiAlN), tantalum nitride (TaN), tantalum aluminum nitride (TaAlN), tungsten (W), tungsten nitride (WN), ruthenium (Ru), ruthenium oxide (RuO₂), strontium ruthenium oxide (SrRuO₃), iridium (Ir), iridium oxide (IrO₂), platinum (Pt), platinum oxide (PtO), SrRuO₃ (SRO), (Ba,Sr)RuO₃ (BSRO), CaRuO₃ (CRO), (La,Sr)CoO₃) (LSCo), or a combination thereof. To form the conductive film 350 for forming lower electrodes, a CVD process, a metal organic CVD (MOCVD) process, or an atomic layer deposition (ALD) process may be used.

Referring to FIG. 3G, an upper side of the conductive film 350 for forming lower electrodes may be partially removed, thereby dividing the conductive film 350 for forming lower electrodes into a plurality of lower electrodes LE.

To form the plurality of lower electrodes LE, a portion of the upper side of the conductive film 350 for forming lower electrodes and the sacrificial pattern 342P (refer to FIG. 3F) may be removed by using an etchback or chemical mechanical polishing (CMP) process so that a top surface of the mold pattern 330P is exposed.

Referring to FIG. 3H, outer surfaces of the plurality of lower electrodes LE may be exposed by removing the mold pattern 330P from the resultant structure of FIG. 3G. The mold pattern 330P may be removed by a lift-off process using an etchant including ammonium fluoride (NH₄F), hydrofluoric acid (HF), and water.

Referring to FIG. 3I, a dielectric film 360 may be formed on the plurality of lower electrodes LE. The dielectric film 360 may conformally cover exposed surfaces of the plurality of lower electrodes LE.

In an implementation, the dielectric film 360 may include, e.g., hafnium oxide, hafnium oxynitride, hafnium silicon oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof. The dielectric film 360 may be formed using an ALD process. The dielectric film 360 may have a thickness of, e.g., about 50 Å to about 150 Å.

Referring to FIG. 3J, an upper electrode UE may be formed on the dielectric film 360. The lower electrode LE, the dielectric film 360, and the upper electrode UE may constitute a capacitor 370.

The upper electrode UE may include a doped semiconductor, a conductive metal nitride, metal, metal silicide, a conductive oxide, or a combination thereof. In an implementation, the upper electrode UE may include, e.g., NbN, TiN, TiAlN, TaN, TaAlN, W, WN, Ru, RuO₂, SrRuO3, Ir, IrO₂, Pt, PtO, SRO(SrRuO₃), BSRO((Ba,Sr)RuO₃), CRO(CaRuO₃), LSCo((La,Sr)CoO₃), or a combination thereof. To form the upper electrode UE, a CVD process, an MOCVD process, a physical vapor deposition (PVD) process, or an ALD process may be used.

In an implementation, in the method of manufacturing the IC device 300, which has been described with reference to FIGS. 3A to 3J, each of the plurality of lower electrodes LE may have a pillar shape. In an implementation, each of the plurality of lower electrodes LE may include a sectional structure having a cup shape or a cylindrical shape with a closed bottom.

In the IC device 300 manufactured using the method described with reference to FIGS. 3A to 3J, the capacitor 370 may include a lower electrode LE having a three-dimensional (3D) electrode structure. To compensate for a reduction in capacitance due to a reduction in design rule, an aspect ratio of the lower electrode LE having the 3D electrode structure has increased. Accordingly, it may be necessary to form the plurality of holes (refer to SH in FIG. 3E), each of which has a deep and narrow 3D space. According to the embodiments, to form the plurality of vertical holes SH, as in the processes of forming the plurality of vertical holes H2, which have been described above with reference to FIGS. 2B to 2G, a hardmask structure pattern HMP may be formed using the hardmask coating layer 40, which is obtained from a hardmask composition including a hardmask-forming compound according to embodiments and a solvent, and the sacrificial film 342 and the mold film 330 may be anisotropically etched using the hardmask structure pattern HMP as an etch mask. During the anisotropic etching process for forming the plurality of vertical holes SH, the sacrificial film 342 and the mold film 330 may be etched in a state in which the boron-containing hardmask pattern 40P reliably remains adhered to hardmask patterns adjacent thereto in the hardmask structure pattern HMP, and the hardmask structure pattern HMP including the boron-containing hardmask pattern 40P may provide an excellent etching resistance. Thus, even when the plurality of vertical holes SH have a relatively high aspect ratio, the plurality of vertical holes SH may obtain a desired vertical profile and a desired etch rate. Accordingly, the reliability of the IC device 300 may be obtained, and productivity in the process of manufacturing the IC device 300 may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Example 1

### Synthesis of Hardmask-Forming Compound A (Hereinafter, Compound A)

A boron compound of Formula 3 and a boron compound of Formula 4 were used as reactants.

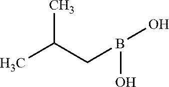

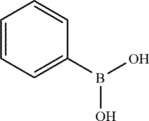

2.6 g of the boron compound of Formula 3 and 3.1 g of the boron compound of Formula 4 were added to a mixture of 120 g of methanol, 1 g of 70 % nitric acid, and 60 g of DIW, and the obtained mixture was subjected to hydrolysis and condensation reactions for about 12 hours while maintaining a temperature of about 40° C. After completion of the reaction, 300 g of propylene glycol ethyl ether (PGEE) was added, and alcohol and excess water as by-products were removed under reduced pressure to obtain 290 g of a PGEE solution containing compound A (polymer concentration of about 12% by weight). A polystyrene conversion molecular weight (Mw) of the obtained compound A was about 1,100.

1HNMR data (ppm relative to tetramethylsilane) of the obtained compound A

4.20(OH), 9.20(OH), 7.75(CH), 7.35(CH), 7.36 (CH), 1.70(CH), 0.49(CH₂), 0.93(CH₃)

### Synthesis Example 2

### Synthesis of Hardmask-Forming Compound B (Hereinafter, Compound B)

A boron compound of Formula 5 and a boron compound of Formula 6 were used as reactants.

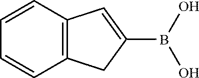 [SMILES: OB(O)C1=Cc2ccccc2C1]

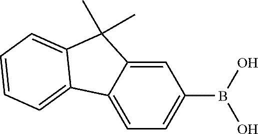 [SMILES: CC1(C)c2ccccc2-c2ccc(B(O)O)cc21]

4.0 g of the boron compound of Formula 5 and 6.0 g of the boron compound of Formula 6 were added to a mixture of 120 g of methanol, 1 g of 70 % nitric acid, and 60 g of DIW, and the obtained mixture was subjected to hydrolysis and condensation reactions for about 12 hours while maintaining a temperature of about 40° C. After completion of the reaction, 300 g of PGEE was added, and alcohol and excess water as by-products were removed under reduced pressure to obtain 290 g of a PGEE solution containing compound B (polymer concentration of about 11% by weight). A polystyrene conversion molecular weight (Mw) of the obtained compound B was about 1,500.

1HNMR data (ppm relative to tetramethylsilane) of the obtained compound B

4.20(OH), 3.22(CH2), 7.62(CH), 7.33 (CH), 7.34(CH), 7.90(CH), 7.37(CH), 7.16(CH), 7.06(CH), 7.21(CH), 1.69(CH₃), 6.6(H)

### Synthesis Example 3

### Synthesis of Hardmask-Forming Compound C (Hereinafter, Compound C)

A boron compound of Formula 7 and a boron compound of Formula 8 were used as reactants.

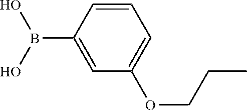

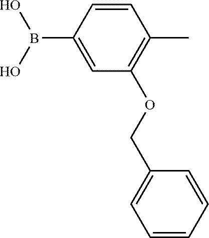 [SMILES: Cc1ccc(B(O)O)cc1OCc1ccccc1]

4.2 g of the boron compound of Formula 7 and 6.1 g of the boron compound of Formula 8 were added to a mixture of 120 g of methanol, 1 g of 70% nitric acid, and 60 g of DIW, and the obtained mixture was subjected to hydrolysis and condensation reactions for about 12 hours while maintaining a temperature of about 40° C. after completion of the reaction, 300 g of PGEE was added, and alcohol and excess water as by-products were removed under reduced pressure to obtain 290 g of a PGEE solution containing compound C (polymer concentration of about 10% by weight). A polystyrene conversion molecular weight (Mw) of the obtained compound C was about 1,500.

1HNMR data (ppm relative to tetramethylsilane) of the obtained compound C

4.20(OH), 6.90(CH), 6.94(CH), 7.16(CH), 7.48(CH), 6.95(CH), 7.38(CH), 7.48(CH), 7.43(CH), 7.40(CH), 7.35(CH), 7.32(CH), 5.16(CH₂), 4.06(CH₂), 2.15(CH₃), 1.34(CH₃)

### Evaluation Example

Boron-containing hardmask layers obtained from hardmask compositions respectively including the hardmask-forming compounds A, B, and C obtained in Synthesis Examples 1 to 3 were formed on a silicon oxide film to be etched.

To form the boron-containing hardmask layers, the silicon oxide film to be etched was coated with the hardmask compositions, which were respectively obtained from the hardmask-forming compounds A, B, and C obtained in Synthesis Examples 1 to 3, to form hardmask coating layers. The obtained hardmask coating layers were annealed under various conditions to form the boron-containing hardmask layers.

Table 1 shows the results of evaluating etching resistance characteristics and the occurrence of peeling-off depending on annealing conditions involved in a process of forming each of the boron-containing hardmask layers.

Table 1 shows the results of evaluating etching resistance characteristics and the occurrence of peeling-off of each of a comparative hardmask layer (Comparative Example 1), which was obtained by annealing a coating layer obtained from a Comparative Compound, and a boron-containing amorphous carbon layer (ACL) (Comparative Example 2).

The Comparative Compound of Comparative Example 1 had the following structure.

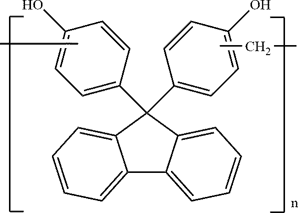

In the Comparative Compound, n was in a range of 30 to 40.

To form the boron-containing ACL used to evaluate Comparative Example 2, C₂H₂ (250 sccm), Ar (1,750 sccm), He (550 sccm), and B₂H₂ (2,000 sccm) were supplied onto a silicon oxide film by using a PECVD system (P5000, Applied materials) under the conditions of a pressure of about 7 Torr, a temperature of about 400° C., and a plasma power of about 700 W. After the boron-containing ACL was formed, no additional annealing process was performed on the boron-containing ACL.

In Table 1, “etch selectivity” refers to a ratio of an etched thickness of a hardmask layer to be evaluated to an etched thickness of a silicon oxide film to be etched. X indicates that no peeling-off occurred between the hardmask layer to be evaluated and the silicon oxide film, Δ indicates the occurrence of relatively little peeling-off between the hardmask layer to be evaluated and the silicon oxide film, and o indicates the occurrence of relatively much peeling-off between the hardmask layer to be evaluated and the silicon oxide film.

TABLE 1

| | | Annealing conditions | Elemental composition of hardmask layer (at%) (C/H/B/O) | Etch selectivity | Peeling-off |
|---|---|---|---|---|---|
| Example 1 | Compound A | 400° C. 90 seconds | 51/6/14/29 | 2.10 | X |
| Example 2 | Compound A | 400° C. 180 seconds | 38/5/17/40 | 2.25 | X |
| Example 3 | Compound A | 500° C. 90 seconds | 25/3/20/52 | 2.43 | X |
| Example 4 | Compound A | 600° C. 90 seconds | 6/1/24/69 | 2.48 | X |
| Example 5 | Compound B | 400° C. 30 seconds | 71/5/8/16 | 1.53 | Δ |
| Example 6 | Compound B | 400° C. 120 seconds | 55/4/12/29 | 2.05 | X |
| Example 7 | Compound C | 400° C. 60 seconds | 66/7/7/21 | 1.48 | Δ |
| Example 8 | Compound C | 400° C. 150 seconds | 28/3/18/52 | 2.18 | X |
| Comparative Example 1 | Comparative Compound | 400° C. 120 seconds | 70/20/0/10 | 1.55 | o |
| Comparative Example 2 | Boron-containing ACL | - | 40/0/59/1 | 3.56 | o |

From the results of Table 1, it may be seen that the etch selectivity of the boron-containing hardmask layers respectively obtained from the hardmask-forming Compounds A, B, and C increased as an annealing time became longer under the same annealing temperature condition. In addition, it may be seen that the etch selectivity of the boron-containing hardmask layers obtained from Compound A increased as an annealing temperature became higher for the same annealing time. Furthermore, in the results of Table 1, it may be seen that peeling-off did not occur when a boron content was greater than about 10 at% and an oxygen content was greater than about 10 at% in the boron-containing hardmask layers respectively obtained from the compounds A, B, and C.

By way of summation and review, as a coverage of the hardmask layer widens in the process of manufacturing the IC device with the high integration, new materials and process techniques have been considered.

One or more embodiments may provide a boron-containing hardmask-forming compound, a hardmask composition including the boron-containing hardmask-forming compound, and a method of manufacturing an IC device using the hardmask composition.

One or more embodiments may provide a polymer, which may provide excellent etching resistance characteristics during a process of manufacturing an integrated circuit (IC) device with a high integration and also may provide excellent adhesion characteristics without causing defects (e.g., peeling-off) in an etching mask structure having a multilayered structure when used as a material for a portion of the etching mask structure in an etching process for forming a pattern having a relatively high aspect ratio, and a hardmask composition including the polymer.

One or more embodiments may provide a method of manufacturing an IC device, whereby a desired vertical profile and a desired etch rate may be obtained by using a hardmask layer including a polymer having excellent adhesion characteristics and excellent etching resistance characteristics when a plasma etching process is performed to form a pattern having a relatively high aspect ratio, and may improve reliability and productivity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask-forming compound including a moiety represented by Formula 1: 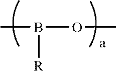
wherein, in Formula 1,
R is a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, or a combination thereof,
each R is separate or forms a ring along with a boron atom included in Formula 1, and
a is an integer ranging from 1 to 50.

2. The hardmask-forming compound as claimed in claim 1, wherein, in Formula 1, R is a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, or a combination thereof.

3. The hardmask-forming compound as claimed in claim 1, wherein:
in Formula 1, R is a group represented by Formula 1A: 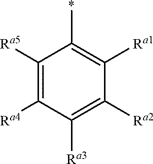
in Formula 1A,
R^{a1}, R^{a2}, R^{a3}, R^{a4}, and R^{a5} are each independnetly a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof,
R^{a1}, R^{a2}, R^{a3}, R^{a4}, and R^{a5} are separate or at least one of R^{a1}, R^{a2}, R^{a3}, R^{a4}, and R^{a5} forms a ring along with another atom included in Formula 1A, and
* denotes a bonding site.

4. The hardmask-forming compound as claimed in claim 1, wherein:
in Formula 1, R is a group represented by Formula 1B: 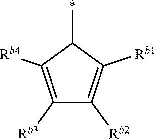
in Formula 1B,
R^{b1}, R^{b2}, R^{b3}, and R^{b4} are each independently a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof,
R^{b1}, R^{b2}, R^{b3}, and R^{b4} are separate, or at least one of R^{b1}, R^{b2}, R^{b3}, and R^{b4} forms a ring along with another atom included in Formula 1B, and
* denotes a bonding site.

5. The hardmask-forming compound as claimed in claim 1, wherein, in Formula 1, R includes a fused polycyclic group.

6. A hardmask-forming compound including a moiety represented by Formula 2: 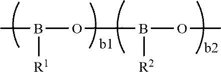
wherein, in Formula 2,
R¹ and R² have different structures from each other,
R¹ and R² are each independently a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof,
R¹ and R² are each separately present, or at least one of R¹ and R² forms a ring along with a boron atom included in Formula 2,
b1 and b2 are each independently an integer ranging from 1 to 50, and
b1/(b1+b2) is in a range of 0.1 to 0.9.

7. The hardmask-forming compound as claimed in claim 6, wherein, in Formula 2, one of R¹ and R² is a substituted or unsubstituted C1 to C30 alkyl group, a substituted or unsubstituted C2 to C30 alkenyl group, a substituted or unsubstituted C3 to C30 alkynyl group, a substituted or unsubstituted C1 to C30 alkoxy group, or a combination thereof.

8. The hardmask-forming compound as claimed in claim 6, wherein:
in Formula 2, one of R¹ and R² is a group represented by Formula 1A: 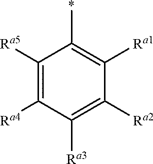
in Formula 1A,
R^{a1}, R^{a2}, R^{a3}, R^{a4}, and R^{a5} are each independnetly a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof,
R^{a1}, R^{a2}, R^{a3}, R^{a4}, and R^{a5} are separate or at least one of R^{a1}, R^{a2}, R^{a3}, R^{a4}, and R^{a5} forms a ring along with another atom included in Formula 1A, and
* denotes a bonding site.

9. The hardmask-forming compound as claimed in claim 6, wherein:
in Formula 2, one of R¹ and R² is a group represented by Formula 1B: 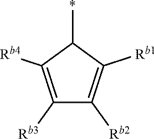
in Formula 1B,
R^{b1}, R^{b2}, R^{b3}, and R^{b4} are each independently a hydrogen atom, a hydroxy group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C1 to C20 heteroalkyl group, a substituted or unsubstituted C1 to C20 alkylamine group, a substituted or unsubstituted C1 to C20 alky ether group, a substituted or unsubstituted C1 to C20 haloalkyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C7 to C20 arylalkyl group, a substituted or unsubstituted C3 to C20 heterocyclic group, a substituted or unsubstituted C7 to C20 arylalkylene ether group, or a combination thereof,
R^{b1}, R^{b2}, R^{b3}, and R^{b4} are separate, or at least one of R^{b1}, R^{b2}, R^{b3}, and R^{b4} forms a ring along with another atom included in Formula 1B, and
* denotes a bonding site.

10. The hardmask-forming compound as claimed in claim 6, wherein, in Formula 2, one of R¹ and R² includes a fused polycyclic group.

11. A hardmask composition, comprising:
the hardmask-forming compound as claimed in claim 1; and
a solvent.

12. A hardmask composition, comprising:
the hardmask-forming compound as claimed in claim 6; and
a solvent.

13. A method of manufacturing an integrated circuit, the method comprising:
forming a target structure on a substrate;
forming a boron-containing hardmask structure on the target structure;
forming a boron-containing hardmask structure pattern having an opening by etching the boron-containing hardmask structure; and
forming a vertical hole by etching the target structure using the boron-containing hardmask structure pattern as an etch mask, the vertical hole passing through at least a portion of the target structure,
wherein forming the boron-containing hardmask structure includes:
forming a hardmask coating layer on the target structure using a hardmask composition including a polymerized product of a boric acid that includes an organic protecting group bonded to a boron atom; and
forming a boron-containing hardmask layer by annealing the hardmask coating layer, the boron-containing hardmask layer including a network system in a cross-linked network structure obtained by cross-linking the polymerized product of the boric acid.

14. The method as claimed in claim 13, wherein:
the hardmask composition used during forming the hardmask coating layer includes a solvent and a hardmask-forming compound including a moiety represented by Formula 1: 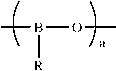
in Formula 1,
R is a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, or a combination thereof,
each R is separate or forms a ring along with a boron atom included in Formula 1, and
a is an integer ranging from 1 to 50.

15. The method as claimed in claim 13, wherein:
the hardmask composition used during forming the hardmask coating layer includes a solvent and a hardmask-forming compound including a moiety represented by Formula 2: 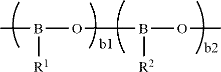
in Formula 2,
R¹ and R² have different structures from each other,
R¹ and R² are each independently a substituted or unsubstituted C1 to C30 alkyl group, a substituted or unsubstituted C1 to C30 alkoxy group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C1 to C30 alkylamine group, a substituted or unsubstituted C1 to C30 alky ether group, a substituted or unsubstituted C1 to C30 haloalkyl group, a substituted or unsubstituted C3 to C30 cycloalkyl group, a substituted or unsubstituted C3 to C30 cycloalkenyl group, a substituted or unsubstituted C6 to C30 aryl group, a substituted or unsubstituted C7 to C30 arylalkyl group, a substituted or unsubstituted C3 to C30 heterocyclic group, a substituted or unsubstituted C7 to C30 arylalkylene ether group, and a combination thereof,
R¹ and R² are each separately present, or at least one of R¹ and R² forms a ring along with a boron atom included in Formula 2,
b1 and b2 are each independently an integer ranging from 1 to 50, and
b1/(b1+b2) is in a range of 0.1 to 0.9.

16. The method as claimed in claim 13, wherein the boron-containing hardmask layer includes a moiety having the following structure, in which * denotes a bonding site: 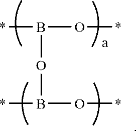
.

17. The method as claimed in claim 13, wherein, in the boron-containing hardmask layer:
a content of boron atoms is in a range of about 10 atomic percent (at%) to about 35 at%, and
a content of oxygen atoms is in a range of about 10 at% to about 70 at%.

18. The method as claimed in claim 13, wherein:
forming the boron-containing hardmask structure further includes forming a lower hardmask layer containing silicon on the target structure prior to forming the hardmask coating layer, and
during forming the hardmask coating layer, a bottom surface of the hardmask coating layer is in contact with a top surface of the lower hardmask layer.

19. The method as claimed in claim 13, wherein:
forming the boron-containing hardmask structure further includes forming an upper hardmask layer containing silicon on the hardmask coating layer after forming the hardmask coating layer, and
during the forming of the upper hardmask layer, a bottom surface of the upper hardmask layer is in contact with a top surface of the hardmask coating layer.

20. The method as claimed in claim 13, further comprising, after forming the vertical hole:
forming a lower electrode of a capacitor inside the vertical hole; and
exposing a surface of the lower electrode by removing the target structure, after forming the lower electrode.
